(19) United States
(12) Patent Application Publication
(10) Pub. No.: US 2014/0162575 A1
(43) Pub. Date: Jun. 12, 2014

(54) HIGHLY INTEGRATED MILLIMETER-WAVE SOC LAYOUT TECHNIQUES FOR IMPROVED PERFORMANCE AND MODELING ACCURACY

(71) Applicant: ANAYAS360.COM, LLC, Sunnyvale, CA (US)

(72) Inventor: Joy Laskar, Los Altos, CA (US)

(73) Assignee: ANAYAS360.COM, LLC, Sunnyvale, CA (US)

(21) Appl. No.: 14/099,407

(22) Filed: Dec. 6, 2013

Related U.S. Application Data
(60) Provisional application No. 61/734,907, filed on Dec. 7, 2012.
(60) Provisional application No. 61/734,882, filed on Dec. 7, 2012.
(60) Provisional application No. 61/734,878, filed on Dec. 7, 2012.

(51) Int. Cl. H01L 49/02; H04B 1/40

(52) U.S. Cl. CPC H01L 28/75; H04B 1/40
USPC 455/90.2; 257/532

(57) ABSTRACT

A capacitor integrated circuit can include a top metal layer, a bottom metal layer, and an intermediate metal layer. The top metal layer can store energy received from a transmission signal in an electric field. The top metal layer can include a first comb structure and a second comb structure, where the first comb structure can be interleaved with the second comb structure. The bottom metal layer can be positioned underneath the top metal layer and can provide a path to ground. The intermediate metal layer can be positioned over the bottom metal layer and underneath at least a portion of the top metal layer. The intermediate metal layer can provide a signal path for a supply voltage.

### CROSS-REFERENCE TO RELATED APPLICATIONS

This application claims priority to U.S. Provisional Patent Application No. 61/734,907, entitled “ADAPTIVE TUNING VOLTAGE BUFFER FOR MILLIMETER-WAVE MULTI-CHANNEL FREQUENCY SYNTHESIZER EXAMPLE EMBODIMENTS” and filed on Dec. 7, 2012, to U.S. Provisional Patent Application No. 61/734,882, entitled “HIGHLY INTEGRATED MILLIMETER-WAVE SOC LAYOUT TECHNIQUES FOR IMPROVED PERFORMANCE AND MODELING ACCURACY” and filed on Dec. 7, 2012, and to U.S. Provisional Patent Application No. 61/734,878, entitled “ON-CHIP CALIBRATION AND BUILT-IN-SELF-TEST FOR SOC MILLIMETER-WAVE INTEGRATED DIGITAL RADIO AND MODEM” and filed on Dec. 7, 2012, the entire contents of which disclosures are herewith incorporated by reference.

This application is related to U.S. patent application Ser. No. ______, entitled “ADAPTIVE TUNING VOLTAGE BUFFER FOR MILLIMETER-WAVE MULTI-CHANNEL FREQUENCY SYNTHESIZER EXAMPLE EMBODIMENTS” and filed on ______ [Attorney Docket No. ANAYA.004A], and U.S. patent application Ser. No. ______, entitled “ON-CHIP CALIBRATION AND BUILT-IN-SELF-TEST FOR SOC MILLIMETER-WAVE INTEGRATED DIGITAL RADIO AND MODEM” and filed on [Attorney Docket No. ANAYA.006A], the entire contents of which disclosures are herewith incorporated by reference.

### BACKGROUND

Consumer electronics may be equipped with communication devices that permit the wireless transfer of data. For example, consumer electronics can include Wi-Fi chips to communicate via the IEEE 802.11 standard, Bluetooth chips to communicate via the Bluetooth communication protocols, or other such chips. As wireless communication technology has improved, more and more data is being transferred using wireless means.

Traditionally, large data files (e.g., audio files, video files, uncompressed image files, such as in the RAW format, etc.) have been transferred using conventional wired protocols even as wireless communication technology has improved due to the power consumption and delay associated with transferring such large data files. However, the ability to transfer large data files wirelessly from one electronic device to another may benefit both users and the manufacturers of electronic devices that manage these large data files if power consumption and delay can be reduced. Users may see a reduction in incompatibility issues between devices and less clutter. As for manufacturers, the connection ports and cables often dictate the shape and size of the electronic device. In fact, because cables and connectors should be large enough so that they can be handled by adult humans, electronic devices are often designed to be larger than they otherwise need to be. Thus, the ability to transfer large data files wirelessly could significantly reduce the form factor of electronic devices that manage large data files.

Transceivers receive and transmit signals, typically wirelessly via an antenna. The shape and size of an electronic device may also be dictated by the size of the transceiver. Thus, the ability to reduce the size of a transceiver could further reduce the form factor of electronic devices that manage large data files.

### SUMMARY

Transceivers may include digital controls and calibration systems in addition to the components used to transmit and receive signals. As data rates increase, there are ever-increasing demands for compact transceivers fabricated using innovative layout techniques so that the transceivers have improved performance across variations in process, voltage, and temperature and improved performance in modeling accuracy. In fact, because transceivers include different types of circuits using both active and passive devices, systematic layout integration strategies may be desired to ensure integrated chip performance. Typically, sensitive portions of a transceiver may be secluded from the remaining portion of the chip to ensure proper operation of the sensitive components. However, this approach may not be suitable for the high level of integration used to achieve the desired compactness of the transceiver.

Accordingly, several embodiments of layout and integration techniques are described herein, which may provide increased accuracy in active and/or passive device modeling and improved integrated circuit performance. For example, building blocks of a transceiver are described that may include supply voltage routing structured in a manner that may reduce supply resistance and enable low-resistance routing of supply voltage to internal building block elements.

In addition, a local oscillator (LO), such as a voltage controlled oscillator (VCO), can be a block of a transceiver system that can affect the quality of the modulation and demodulation techniques. Any noise or signal coupling in the signal path or route of the tuning control voltage signal of the LO can be upconverted at the output of the LO, thereby degrading the transmitter and/or receiver performance. While noise or signal coupling issues can be handled using additional processing and features, such additional processing and features may lead to the tuning control voltage signal being routed over a long distance. Routing the tuning control voltage signal over a long distance may introduce noise into the signal and degrade the performance of the transceiver system.

Accordingly, several embodiments of different custom layout techniques are described herein that can maintain the signal integrity and/or performance of different building blocks in a complex mixed-signal (e.g., RF, analog, digital, MMW, etc.) signal environment. Such custom layout techniques may include using a tunnel-like layout structure, using an intermediate metal layer as the ground layer, and/or routing control signals using a set or array of unit cells, among other techniques.

One aspect of the disclosure provides a capacitor integrated circuit comprising a top metal layer configured to store energy received from a transmission signal, the top metal layer comprising a first comb structure and a second comb structure. The first comb structure may be interleaved with the second comb structure to form a capacitor. The capacitor integrated circuit further comprises a bottom metal layer positioned underneath the top metal layer. The bottom metal layer may be configured to provide a path to ground. The capacitor integrated circuit further comprises an intermediate metal layer positioned over the bottom metal layer and underneath at least a portion of the top metal layer. The intermediate metal layer may be configured to provide a signal path for a supply voltage.

Another aspect of the disclosure provides a signal route layout comprising a top metal layer configured to provide a path to ground. The signal route layout further comprises a bottom metal layer positioned below the top metal layer. The bottom metal layer may be configured to provide a path to ground. The signal route layout further comprises a first set of via sidewalls configured to couple a left side of the top metal layer to a left side of the bottom metal layer. The signal route layout further comprises a second set of via sidewalls configured to couple a right side of the top metal layer to a right side of the bottom metal layer. The signal route layout further comprises an intermediate metal layer positioned between the top metal layer and the bottom metal layer and between the first set of via sidewalls and the second set of via sidewalls. The intermediate metal layer may be configured to provide a path for a transmission signal.

Another aspect of the disclosure provides a signal route layout comprising a top metal layer configured to provide a path for a transmission signal. The signal route layout further comprises a bottom metal layer configured to provide a path for a non-transmission signal. The signal route layout further comprises an intermediate metal layer positioned between the top metal layer and the bottom metal layer. The intermediate metal layer may be configured to provide a path to ground.

Another aspect of the disclosure provides a wireless data transceiver comprising a wireless receiver. The wireless data transceiver further comprises a wireless transmitter. The wireless data transceiver further comprises an interdigitated capacitor comprising a top metal layer configured to store energy received from a transmission signal. The top metal layer may comprise a first comb structure and a second comb structure. The first comb structure may be interleaved with the second comb structure. The interdigitated capacitor may further comprise a bottom metal layer positioned underneath the top metal layer. The bottom metal layer may be configured to provide a path to ground. The interdigitated capacitor may further comprise an intermediate metal layer positioned over the bottom metal layer and underneath at least a portion of the top metal layer. The intermediate metal layer may be configured to provide a signal path for a supply voltage.

Certain aspects, advantages and novel features of the inventions are described herein. It is to be understood that not necessarily all such advantages may be achieved in accordance with any particular embodiment of the inventions disclosed herein. Thus, the inventions disclosed herein may be embodied or carried out in a manner that achieves or selects one advantage or group of advantages as taught herein without necessarily achieving other advantages as may be taught or suggested herein.

### BRIEF DESCRIPTION OF THE DRAWINGS

Throughout the drawings, reference numbers can be re-used to indicate correspondence between referenced elements. The drawings are provided to illustrate embodiments of the inventions described herein and not to limit the scope thereof.

FIG. 1 illustrates a block diagram of an example MMW transceiver.

FIGS. 2A-2B illustrate an example MMW transceiver die.

FIG. 3A illustrates an example layout of an interdigitated capacitor.

FIG. 3B illustrates an example model of the interdigitated capacitor of FIG. 3A.

FIG. 4 illustrates an example layout for a signal route of a local oscillator.

FIG. 5 illustrates an example transmission line that includes interdigitated capacitors.

FIG. 6 illustrates an example circuit in which inter-line interaction is reduced.

FIG. 7 illustrates an example docking system.

### DETAILED DESCRIPTION

### Introduction

Transceivers that communicate in the millimeter wave (MMW) frequencies may be able to handle the wireless transfer of large data files at high data rates and low power consumption. Accordingly, described herein are transceivers and components thereof that can achieve the goals described above. While aspects of the disclosure are described herein with respect to MMW frequencies, this is not meant to be limiting. As an example, MMW frequencies may be centered at 60 GHz, although higher and lower frequencies may also be considered MMW frequencies. However, the features described herein apply to any device that communicates at high frequencies (e.g., 2.4 GHz, 5 GHz, 20-120 GHz, higher frequencies than 120 GHz, frequencies lower than 20 GHz, and the like).

In an embodiment, MMW transceivers may include digital controls and calibration systems in addition to the components used to transmit and receive signals. As data rates increase, there are ever-increasing demands for compact MMW transceivers fabricated using innovative layout techniques so that the MMW transceivers have improved performance across variations in process, voltage, and temperature and improved performance in modeling accuracy. In fact, because MMW transceivers may include different types of circuits using both active and passive devices (e.g., MMW amplifiers, MMW frequency synthesizers, intermediate frequency (IF) (e.g., >10 GHz) amplifiers and frequency synthesizers, baseband (BB) multi-GHz analog and digital circuits, digital control circuits, etc.), systematic layout integration strategies may be desired to ensure integrated chip performance.

Typically, MMW circuits may be secluded from the remaining portion of the MMW transceiver to ensure proper operation of the sensitive MMW circuit components. However, this approach may not be suitable for the high level of integration used to achieve the desired compactness of the MMW transceiver.

Accordingly, several embodiments of layout and MMW integration techniques are described herein, which may provide increased accuracy in active and/or passive device modeling improved integrated circuit performance. For example, MMW building blocks are described herein that may include supply voltage routing structured in a manner that may reduce supply resistance and enable low-resistance routing of supply voltage to internal MMW building block elements.

In addition, a local oscillator (LO), such as a voltage controlled oscillator (VCO), can be a block of a MMW transceiver system that affect the quality of the modulation and demodulation techniques. Any noise or signal coupling in the signal path or route of the tuning control voltage signal of the LO (e.g., Vₜᵤₙₑ) can be upconverted at the output of the LO, thereby degrading the transmitter and/or receiver performance. While noise or signal coupling issues can be handled using additional processing and features (e.g., a phased-locked loop (PLL) lock detector, a Vₜᵤₙₑ memory circuit used to save the locked Vₜᵤₙₑ voltage under PLL operation, etc.), such additional processing and features may lead to the Vₜᵤₙₑ signal being routed over a long distance. Routing Vtune over a long distance may introduce noise into the signal and degrade the performance of the MMW transceiver system.

Accordingly, several embodiments of different custom layout techniques are described herein that can maintain the signal integrity and/or performance of different building blocks in a complex mixed-signal (e.g., RF, analog, digital, MMW, etc.) signal environment. Such custom layout techniques may include using a tunnel-like layout structure, using an intermediate metal layer as the ground layer, and/or routing control signals using a set or array of unit cells, among other techniques.

Using any of the layout techniques described herein, the MMW transceiver may feature a significantly reduced power consumption. For example, the power consumption in the MMW transceivers may be reduced to less than 250 mW when the MMW transceivers are receiving or transmitting data.

For ease of illustration, various features are described herein with respect to MMW transceivers. However, some or all of these features may also be implemented in other transceivers, receivers, or transmitters designed for wavelengths other than millimeter waves.

Further, the systems and methods described herein can be implemented in any of a variety of electronic devices, including, for example, cell phones, smart phones, personal digital assistants (PDAs), tablets, mini-tablets, laptops, desktops, televisions, digital video recorders (DVRs), set-top boxes, media servers, audio/visual (A/V) receivers, video game systems, high-definition disc players (such as Blu-ray® players), computer peripherals (such as mice, keyboards, scanners, printers, copiers, and displays), universal serial bus (USB) keys, cameras, routers, switches, other network hardware, radios, stereo systems, loudspeakers, sound bars, appliances, vehicles, digital picture frames, and medical devices, to name a few.

For purposes of summarizing this disclosure, certain aspects, advantages and novel features of several embodiments have been described herein. It is to be understood that not necessarily all such advantages can be achieved in accordance with any particular embodiment of the embodiments disclosed herein. Thus, the embodiments disclosed herein can be embodied or carried out in a manner that achieves one advantage or group of advantages as taught herein without necessarily achieving other advantages as taught or suggested herein.

### MMW Transceiver Overview

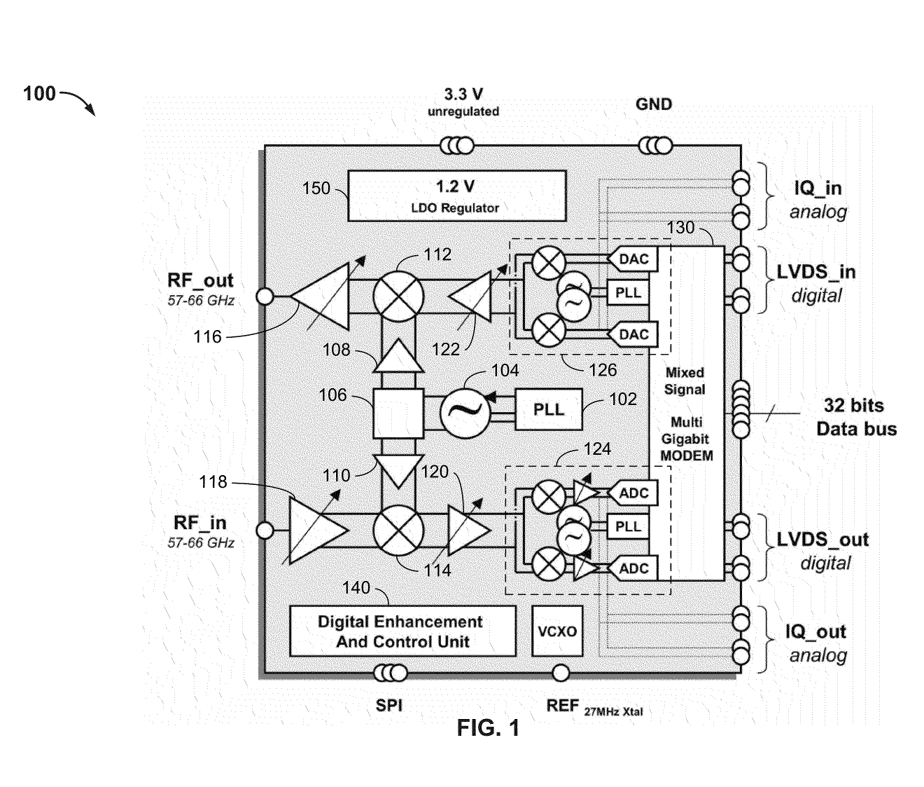

FIG. 1 illustrates a block diagram of an example MMW transceiver 100. As described above, the MMW transceiver 100 includes various input ports, output ports, analog components, and/or digital components. For example, as illustrated in FIG. 1, the MMW transceiver 100 includes an RF_in port and an RF_out port. The RF_in port is configured to receive MMW signals transmitted by another device within a set frequency range (e.g., a MMW frequency range, such as 57-66 GHz, etc.). The RF_out port is configured to transmit MMW signals to one or more devices within a set frequency range (e.g., a MMW frequency range, such as 57-66 GHz, etc.).

The MMW transceiver 100 further includes components to process signals received via the RF_in port and/or generate signals to be transmitted via the RF_out port. For example, the MMW transceiver 100 includes PLL 102, LO 104, signal distribution block (e.g., splitter) 106, gain blocks 108 and 110, up-conversion frequency mixer 112, down-conversion frequency mixer 114, amplifiers 116, 118, 120, and 122, baseband (BB) blocks 124 and 126, mixed-signal modem 130, digital enhancement and control unit 140, and voltage regulator 150. In an embodiment, PLL 102 and LO 104 generate a LO signal that is passed to the signal distribution block 106 and the gain blocks 108 and 110. The signal distribution block 106 can be configured to distribute the LO signal to multiple components. Gain blocks 108 and 110 amplify the LO signal so that the LO signal can properly drive the frequency mixers 112 and/or 114. However, in other embodiments, as described herein, one of more of the gain blocks 108 and/or 110 can be removed.

In some embodiments, the MMW signal received via the RF_in port is passed to amplifier 118. As an example, amplifier 118 may be a low noise amplifier (LNA). The amplifier 118 can adjust the amplitude of the received MMW signal and pass it to the down-conversion frequency mixer 114. The down-conversion frequency mixer 114 can down-convert the MMW signal from a MMW frequency to an intermediate frequency (IF) or a BB frequency using the LO signal. The down-converted signal then passes through amplifier 114 before being processed by the BB blocks 124.

Likewise, the MMW signal transmitted via the RF_out port is generated based on a signal generated by the BB blocks 126 that passes through amplifier 122 and the LO signal. In an embodiment, the signal generated by the BB blocks 126 is a BB or IF signal. The up-conversion frequency mixer 112 upconverts the BB or IF signal to a MMW signal using the LO signal. The MMW signal may pass through amplifier 116 before transmission occurs.

In some embodiments, the mixed-signal modem 130 is a digital component that transmits data to and receives data from other components of an electronic device (e.g., memory, a processor, etc.). For example, the data can be communicated via a 32-bit data bus. Data received by the mixed-signal modem 130 via the data bus can be transferred to the BB blocks 126. Likewise, data received by the mixed-signal modem 130 from the BB blocks 124 can be transferred to other components of the electronic device via the data bus.

Digital enhancement and control unit 140 provides digital means for controlling the various analog and/or digital components of the MMW transceiver 100. For example, digital enhancement and control unit 140 can adjust the characteristic or performance of the amplifier 118, the down-conversion frequency mixer 114, and so on.

In an embodiment, voltage regulator 150 generates an approximately constant voltage (e.g., 1.2V) that is supplied to one or more components of the MMW transceiver 100. The voltage regulator 150 may generate the approximately constant voltage based on an unregulated voltage (e.g., 3.3V) received via a port of the MMW transceiver 100.

### Example Highly Integrated MMW Transceiver Layout Techniques for Improved Performance and Accurate Modeling

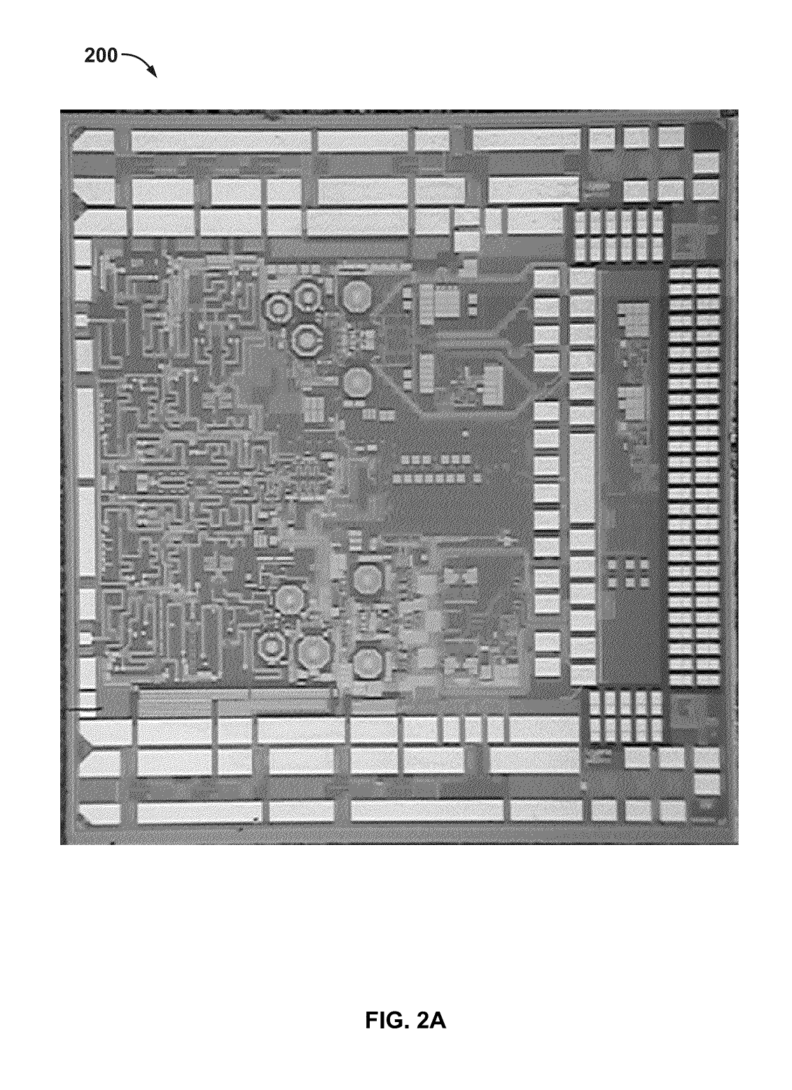

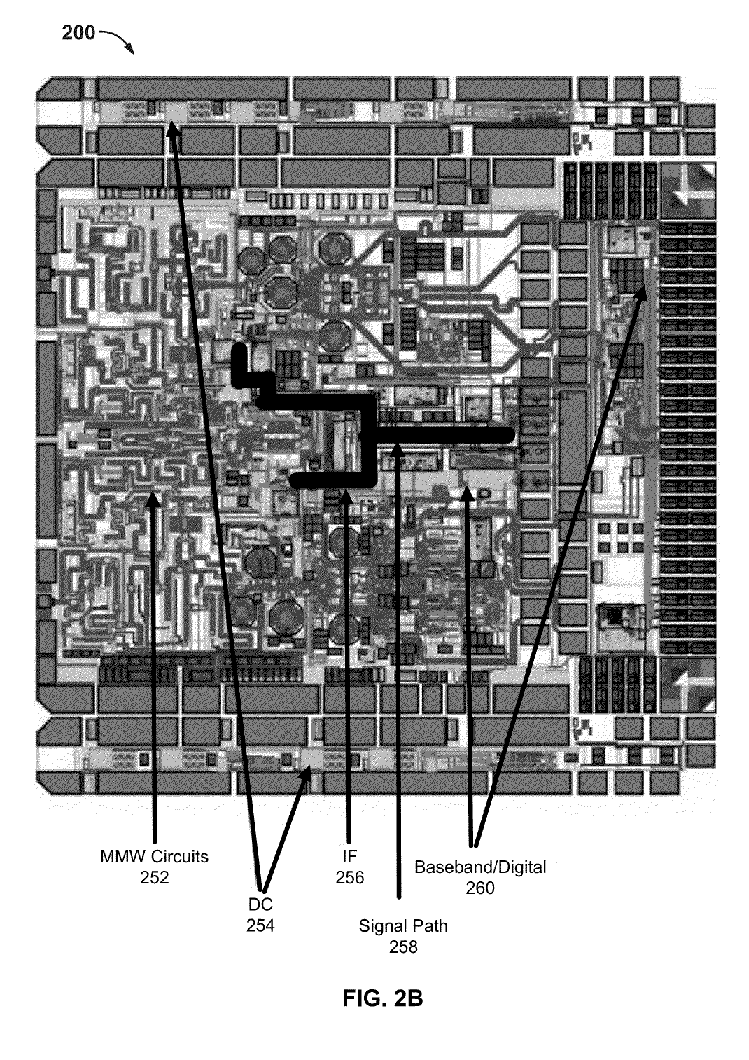

FIGS. 2A-2B illustrate an example MMW transceiver 100 die 200. In an embodiment, FIGS. 2A-2B illustrate an example of an extremely integrated and compact digitally controlled low power 60 GHz transceiver IC. In a further embodiment, the die 200 includes greater than 250,000 gates.

As illustrated in FIG. 2B, the die 200 includes various components of the MMW transceiver 100. For example, the die 200 includes MMW circuits 252, DC circuits 254, IF circuits 256, an example signal path 258, and baseband (BB)/digital circuits 260. In an embodiment, the example signal path 258 is a serial control route.

As described above, in some embodiments, it can be desirable for some or all of the building blocks of the MMW transceiver 100 (e.g., the building blocks in the center of the MMW transceiver 100) to receive the supply voltage from a top layer and a bottom layer coming through other building blocks of the MMW transceiver 100 to maintain the compact integration. For example, capacitors, resistors, inductors, transistors, and/or other components could be designed in such a manner.

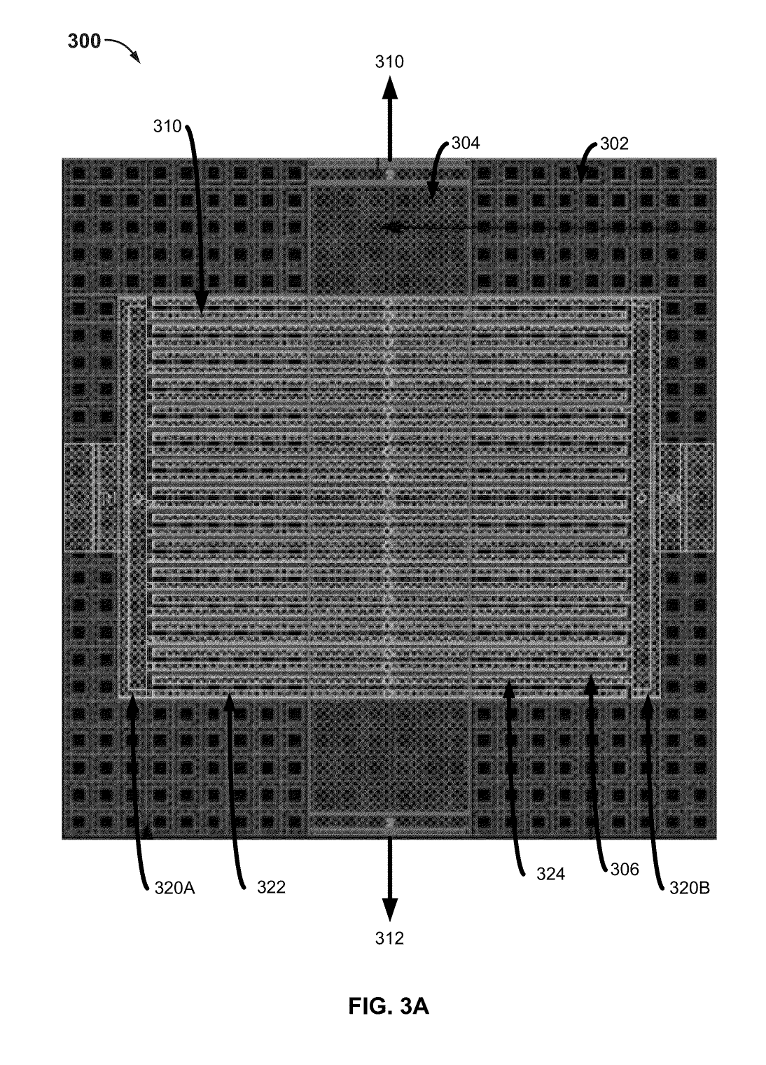

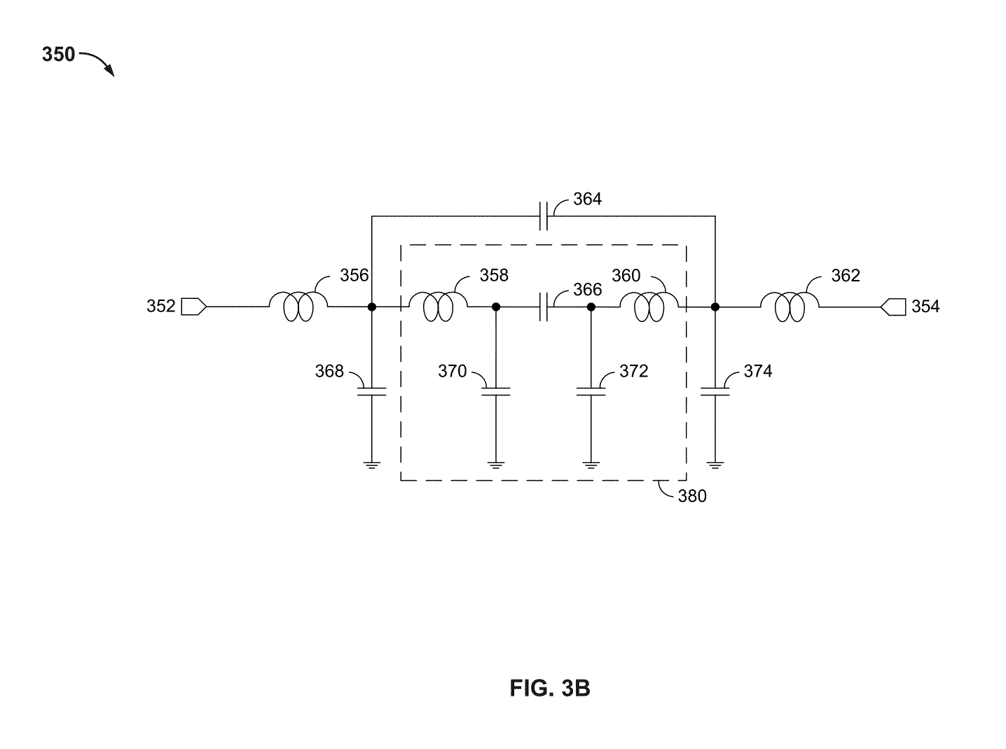

FIG. 3A illustrates an example layout 300 of an interdigitated capacitor 310. In an embodiment, the interdigitated capacitor 310 can be used within the die 200 described above with respect to FIGS. 2A-2B. In some instances, the interdigitated capacitor 310 contributes to the compactness and low power consumption of the die 200. As illustrated in FIG. 3A, the layout 300 of the interdigitated capacitor 310 includes a top metal layer 306, an intermediate metal layer 304, and a bottom metal layer 302. Thus, the top metal layer 306 may overlap the intermediate metal layer 304, and the intermediate metal layer 304 may overlap the bottom metal layer 302.

The thickness of the metal layers 302, 304, and 306 may affect the size of the MMW transceiver 100, the cost to produce the MMW transceiver 100, and/or the power consumption of the MMW transceiver 100. For example, a lower metal thickness may result in a reduction in area, cost, and/or power consumption. In some embodiments, the layout 300 reduces area, cost, and/or power consumption because the intermediate metal layer 304 and/or the bottom metal layer 302 are constructed with a standard thickness (e.g., as specified by a foundry). The top metal layer 306 may be the only metal layer that has a thickness that exceeds the standard thickness. For example, the top metal layer 306 may be thicker than the intermediate metal layer 304 and/or the bottom metal layer 302 by a factor of two or three. Such a design may be possible by routing current into the three metal layers 302, 304, and 306 asymmetrically such that the top metal layer 306 has more current flow than the other two metal layers 302 and 304.

In an embodiment, the interdigitated capacitor 310 is formed using the top metal layer 306. The top metal layer 306 may include a structure that includes two interleaved combs. The two interleaved combs may form the interdigitations of the interdigitated capacitor 310. For example, the top metal layer 306 may include a left bar 320A from which teeth protrude, such as tooth 322, and a right bar 320B from which teeth protrude, such as tooth 324. The teeth protruding from the left bar 320A may protrude in the direction of the teeth that protrude from the right bar 320B to form the interleaved structure. As an example, the left bar 320A may have 15 teeth that protrude out. The right bar 320B may have the same or a different number of teeth that protrude out. However, this is not meant to be limiting. The left bar 320A and/or the right bar 320B can have any number of teeth. The number of teeth may affect the capacitance of the interdigitated capacitor 310 (e.g., more teeth may result in a greater capacitance). In addition, the length of the teeth protruding from the left bar 320A may be of a same length or a different length than the length of the teeth protruding from the right bar 320B.

As illustrated in FIG. 3A, a vertical gap may exist between the interleaved teeth. For example, a vertical gap exists between tooth 322 and tooth 324. The vertical gap may affect the capacitance of the interdigitated capacitor 310 and may be of a varied length. In addition, a horizontal gap may exist between the teeth that protrude from the left bar 320A and the right bar 320B and between the teeth that protrude from the right bar 320B and the left bar 320A. Such a horizontal gap may also be characterized as an amount of overlap between the teeth (e.g., the wider the gap, the less overlap between the teeth). For example, a horizontal gap exists between the tooth 322 and the right bar 320B and a horizontal gap exists between the tooth 324 and the left bar 320A. The horizontal gap may affect the capacitance of the interdigitated capacitor 310 and may be of a varied length.

The interdigitated capacitor 310 may include a supply voltage line crossover designed using the intermediate metal layer 304. For example, the supply voltage may be routed using the intermediate metal layer 304 and cross under at least a portion of the top metal layer 306. The intermediate metal layer 304 and the top metal layer 306 may be coupled together with one or more vias. For example, the vias may be set in one or more rows between a portion of the intermediate metal layer 304 and the top metal layer 306 that overlap. As illustrated in FIG. 3A, the vias can be placed in a row in a center of the intermediate metal layer 304 within an area in which the intermediate metal layer 304 and the top metal layer 306 overlap. Placing vias in the center of the intermediate metal layer 304 within an area in which the intermediate metal layer 304 and the top metal layer 306 overlap, as opposed to on the edges of the intermediate metal layer 304, may reduce parasitic capacitances.

In an embodiment, a ground metal layer 302 is present all around the interdigitated capacitor 310 to ensure or attempt to ensure a proper return path for the MMW signals. One or more vias may be present between the top metal layer 306 and the ground metal layer 302. The vias may be located in a portion of the layout 300 in which the top metal layer 306 and the intermediate metal layer 304 do not overlap. Decoupling capacitors may be present in the voltage supply routing in the intermediate metal layer 304 near a location in which the intermediate metal layer 304 and the top metal layer 306 crossover. The decoupling capacitors in such a location may allow the supply voltage route to behave as an additional ground signal return path for the MMW signals.

FIG. 3B illustrates an example model 350 of the interdigitated capacitor 310 of FIG. 3A. In an embodiment, the model 350 can accurately predict the performance of the interdigitated capacitor 310 structure and enable a low-resistance routing of the supply voltage to the internal MMW circuits. The model 350 may represent the overlapped portion of the interdigitated capacitor 310 (e.g., the top metal layer 306) and the supply voltage lines (e.g., the intermediate metal layer 304).

As illustrated in FIG. 3B, the model 350 includes inductors 356, 358, 360, and 362 and capacitors 364, 366, 368, 370, 372, and 374. Ports 352 and 354 may couple the interdigitated capacitor 310 to other components in an MMW circuit. In an embodiment, the capacitor 364 is located in the top metal layer 306 and represents the interdigitated capacitor 310. The inductors 356, 358, 360, and 362 may represent the inductance of the supply voltage routing in the intermediate metal layer 304. Capacitors 368, 370, 372, and 374 may be decoupling capacitors that provide an additional ground signal return path for the MMW signals. Together, inductors 358 and 360 and capacitors 366, 370, and 372 (e.g., the components within box 380) may be the components of the intermediate metal layer 304 that overlap with the top metal layer 306.

### Example Highly Integrated MMW Transceiver Layout Techniques for Improving Signal Integrity and Performance for MMW SOC Integration

In certain embodiments, different custom layout techniques can be used to maintain the signal integrity and/or performance of different building blocks in a complex mixed-signal (e.g., RF, analog, digital, MMW, etc.) signal environment. For example, LOs, and specifically VCOs, may be designed using different custom layout techniques. Such custom layout techniques may include using a tunnel-like layout structure, using an intermediate metal layer as the ground layer, and/or routing control signals using a set or array of unit cells.

VCOs are building blocks in many transceiver systems, such as the MMW transceiver 100, because a VCO can ensure or attempt to ensure the quality of the modulation and demodulation techniques. For example, any noise or signal coupling in the signal path or route of the tuning control voltage signal of the VCO (e.g., Vₜᵤₙₑ) is upconverted at the output of the VCO, thereby degrading the transmitter and/or receiver performance. Typically, noise or signal coupling issues can be handled using additional processing and features (e.g., a phased-locked loop (PLL) lock detector, a Vₜᵤₙₑ memory circuit used to save the locked Vₜᵤₙₑ voltage under PLL operation, etc.); however, such additional processing and features may lead to the Vₜᵤₙₑ signal being routed over a long distance.

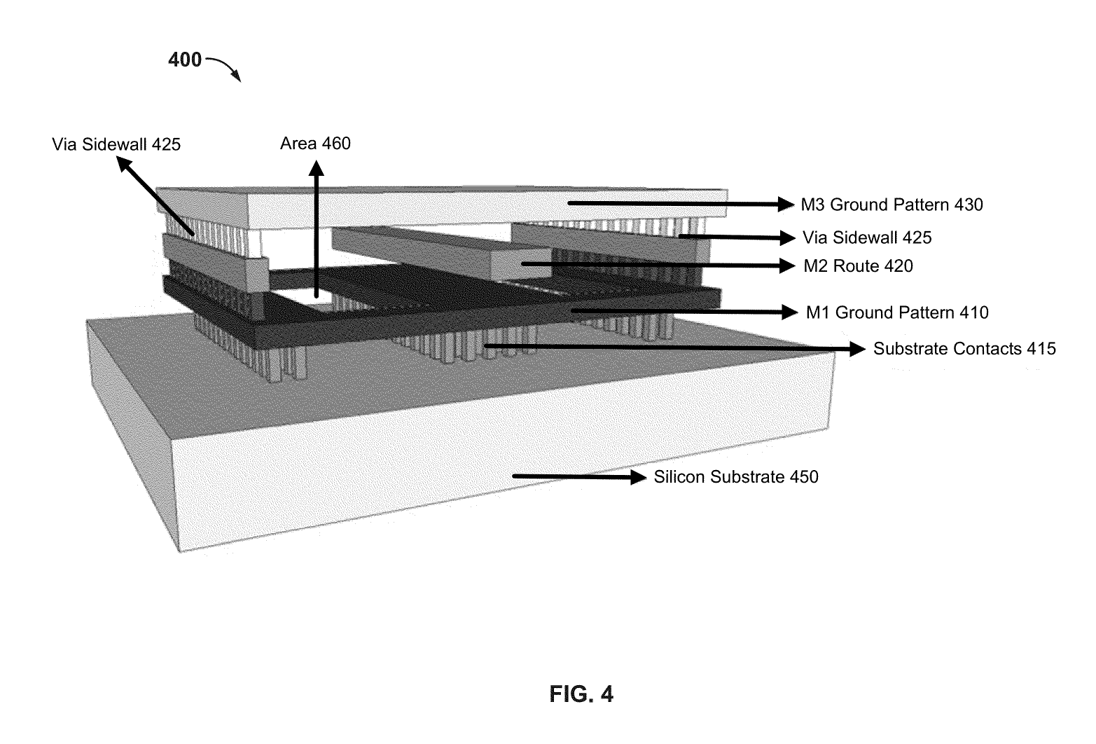

In some embodiments, a custom layout technique is provided for the Vₜᵤₙₑ signal routes to prevent or reduce signal coupling and/or noise. FIG. 4 illustrates an example layout 400 for a signal route of a local oscillator. In an embodiment, the layout 400 includes a tunnel-like layout structure based on the custom layout technique described herein. As illustrated in FIG. 4, the layout 400 includes M1 ground pattern 410, M2 route 420, M3 ground pattern 430, via sidewalls 425, substrate contacts 415, and a silicon substrate 450.

The M1 ground pattern 410, the via sidewalls 425, and the M3 ground pattern 430 may form a tunnel-like structure. The M2 route 420 may be enclosed or placed within the opening of the tunnel-like structure and may be configured to transport the Vₜᵤₙₑ signal. In an embodiment, the M1 ground pattern 410, the M3 ground pattern 430, and/or the via sidewalls 425 prevent or reduce some or all noise from coupling with the M2 route 420. Thus, the M1 ground pattern 410, the M3 ground pattern 430, and/or the via sidewalls 425 at least partially shield the Vₜᵤₙₑ signal from other frequencies. In a further embodiment, the M1 ground pattern 410, the M3 ground pattern 430, and/or the via sidewalls 425 are connected to the silicon substrate 450 (e.g., via substrate contacts 415) to reduce or otherwise minimize any ground noise. As an example, the silicon substrate 450 may be any dielectric, such as silicon dioxide.

In some embodiments, the M1 ground pattern 410 includes a hollow portion, such as area 460. The area 460 may provide better isolation for the Vₜᵤₙₑ signal. For example, the area 460 may filter unwanted harmonics. The degree to which the Vₜᵤₙₑ signal is isolated may depend on the size and/or depth of the area 460. The area 460 may be filled with air or any dielectric.

It can be difficult and nontrivial to design a transmission or routing line in silicon or a similar substrate for compact MMW applications without violating semiconductor foundry design rules or requesting special requirements from the foundry. Some examples of foundry design rules include specifications regarding metal area, material thickness, via hole density, via area, and/or metal to non-metal ratio. A sample set of design rules produced by UMC can be found here: http://www.umc.com/chinese/pdf/UMC%2065nm.pdf. Satisfying the design rules can allow a chip to be mass-producible or manufacturable. Thus, while it may be easier to design a transmission line in a semiconductor device that violates the design rules, such a design may not be mass-producible and may therefore only be useful for academic study.

Further, a transmission or routing line can be set in a bottom metal layer and made as small as possible within the design rules. Any resulting parasitics (e.g., parasitic capacitances) can be factored in when designing other aspects of the chip. Such techniques, though, may result in an increase in an area of the die, which increases cost and signal loss, and may result in inter-line interaction (e.g., unwanted coupling), which degrades the performance of the MMW transceiver. In contrast, the example layout 400 described herein may satisfy foundry design rules (e.g., from a foundry) while reducing or minimizing such consequences (e.g., increased cost and performance degradation). For example, the M1 ground pattern 410, the M2 route 420, the M3 ground pattern 430, and/or the via sidewalls 425 may be of such an area, thickness, hole density, via area, and/or metal to non-metal ratio that satisfies a foundry's design rules. As described above, because the M1 ground pattern 410, the M3 ground pattern 430, and/or the via sidewalls 425 at least partially shield the Vₜᵤₙₑ signal in the M2 route 420, the Vₜᵤₙₑ signal may be decoupled from signals of other frequencies, reducing or eliminating inter-line interaction. Such layout techniques can also be used to decouple or at least partially isolate other signals, such as supply voltage or control signals.

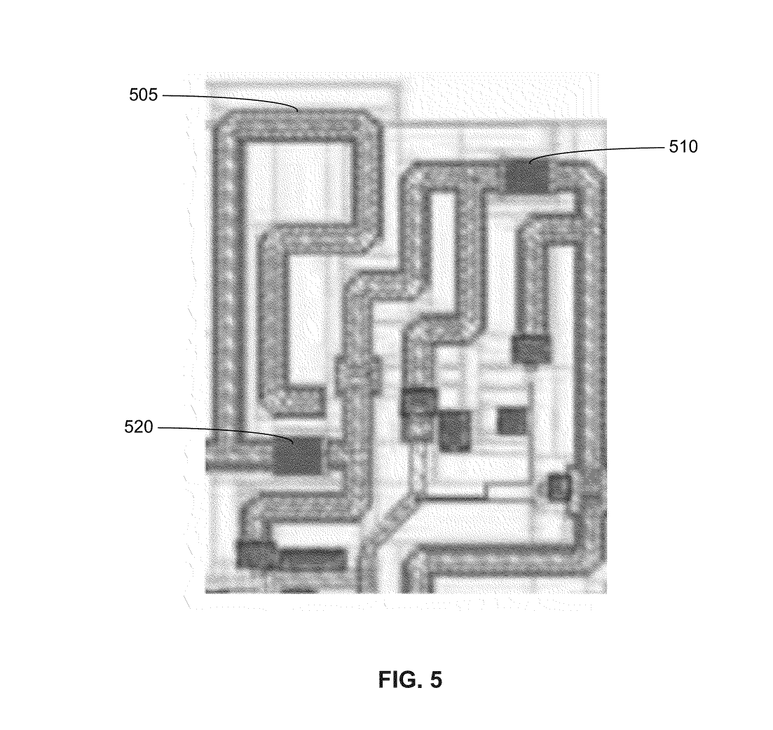

In an embodiment, the layout 400 can be combined with the layout 300 of FIG. 3A. For example, a transmission line comprising one or more of the structures represented in layout 400 occasionally can be combined with the an interdigitated capacitor comprising the structure represented by the layout 300 to provide decoupling in the transmission line (e.g., one or more interdigitated capacitors can be added in the transmission line). FIG. 5 illustrates an example transmission line 505 that includes interdigitated capacitors 510 and 520. In an embodiment, the transmission line 505 includes one or more structures (e.g., coupled together) represented by the layout 400. The interdigitated capacitors 510 and 520 may each include a structure represented by the layout 300. In such an embodiment, the interdigitated capacitor 310 may be present in the M2 route 420 (e.g., the top metal layer 306 of FIG. 3A may be aligned with the M2 route 420 of FIG. 4).

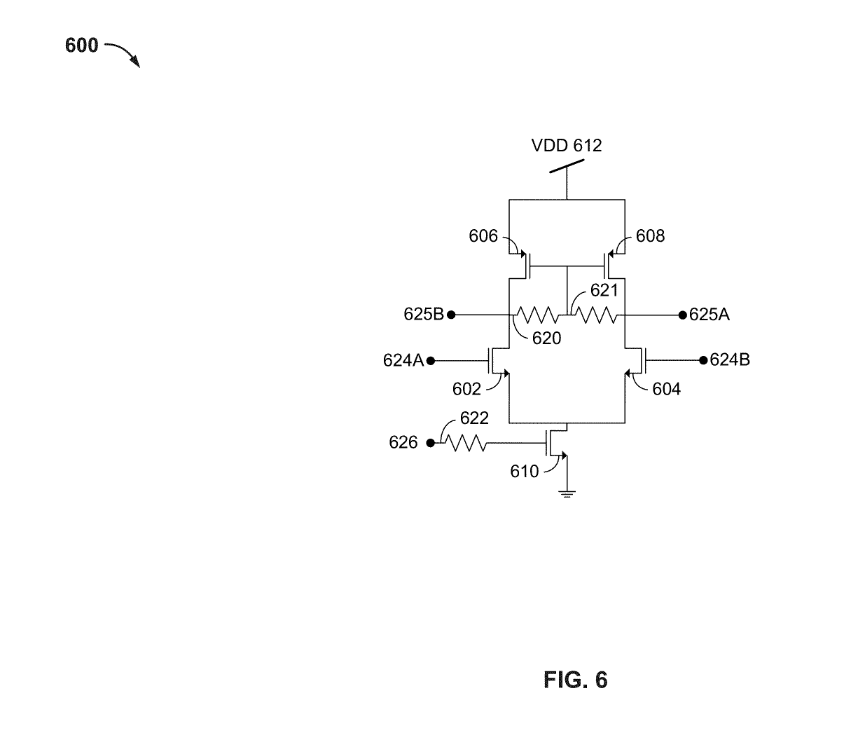

FIG. 6 illustrates an example circuit 600 in which inter-line interaction is reduced. In an embodiment, the circuit 600 is a differential input/output amplifier. The circuit 600 may de-couple a DC and RF path. As illustrated in FIG. 6, the circuit 600 includes transistors 602, 604, 606, 608, and 610 and resistors 620-622. Nodes 624A and 624B may represent inputs to the circuit 600. Nodes 624A and 625B may carry a DC signal. Nodes 625A and 625B may represent outputs to the circuit 600. Nodes 625A and 625B may carry an RF signal. In an embodiment, the DC signal and the RF signal may be de-coupled using layout techniques described herein (e.g., the DC signal and the RF signal may be carried in different metal layers). Furthermore, supply voltage VDD 612 may be de-coupled from the DC signal and/or the RF signal in the same or similar manner. In addition, node 626, which supplies a bias voltage to the transistor 610, may be de-coupled from the DC signal, the RF signal, and/or the supply voltage VDD 612 in the same or similar manner.

In an embodiment, to maintain the signal integrity of the MMW transmission lines, a well-defined high frequency ground return path can be beneficial. For example, a well-defined high frequency ground return path may reduce parasitic capacitances and/or provide enhanced signal isolation. Hence, any signal route in any intermediate metal, such as the intermediate metal layer 304 or the M2 route 420, can impact the field pattern in a transmission line between the top signal layer (e.g., the top metal layer 306, the M3 ground pattern 430, etc.) and bottom ground layer (e.g., the bottom metal layer 302, the M1 ground pattern 410, etc.). In a digitally controlled MMW SOC, one or more control routes can be placed such that the control routes pass through a MMW circuit element (e.g., the interdigitated capacitor 310) to reduce or minimize supply resistances and enable low-resistance routing of supply voltage. In addition, one or more supply voltage routes can be placed such that the supply voltage routes pass through a MMW circuit element to reduce or minimize supply resistances and enable low-resistance routing of supply voltage.

Accordingly, in some embodiments, a transmission line structure can be provided such that the top metal layer, M3 (e.g., the M3 ground pattern 430), is used as the signal layer (e.g., to carry a MMW signal as a MMW transmission line) and the intermediate metal layer, M2 (e.g., M2 route 420), is used as the ground layer. The bottom metal layer, M1 (e.g., M1 ground pattern 410), may be used as a control route or a supply voltage route. In other embodiments, the top metal layer is used as a control or supply voltage route, the intermediate metal layer is used as the ground layer, and the bottom metal layer is used as the signal layer. Thus, because the control or supply voltage route and the MMW transmission line are separated by a ground layer in one embodiment, the control or supply voltage route may have little to no impact on the performance of the MMW transmission line. Vias may be used to couple any combination of the M1, M2, and M3 metal layers.

In an embodiment, serial control signal routing throughout a highly integrated SOC can be beneficial to maintain the signal integrity of the control signals as well as the MMW circuit elements. A modular layout concept can be provided in certain embodiments so that the complete MMW transceiver SOC is divided into different modules (e.g., transmitter front-end, receiver front-end, MMW frequency synthesizer, receiver IF and BB demodulator, transmitter IF and BB modulator, control module, combinations of the same, or the like). The serial control signals can be routed to some or all of the modules utilizing an array of unit cells. For example, one or more unit cells may be connected together. In some embodiments, each unit cell has a continuous ground and supply pattern for easy integration. A unit cell may include a simple interconnect, an interconnect with a buffer, an interconnect with one or more noise-suppressing decoupling capacitors in the power supply, t-junctions for connecting a slave module to the control bus or for connecting two or more control buses, combinations of the same, and/or the like. Any type of unit cell may be coupled to any other type of unit cell.

### Example Use Case

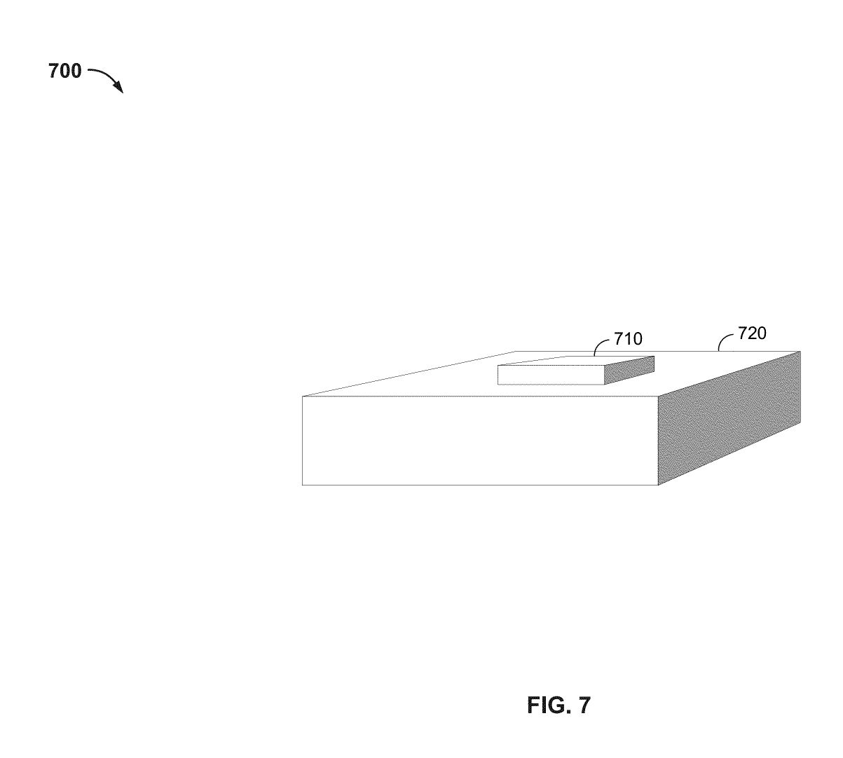

FIG. 7 illustrates an example docking system 700. As illustrated in FIG. 7, the docking system 700 can include an electronic device 710 (e.g., a mobile phone, a tablet, a laptop, etc.) and a docking station 720 (e.g., a television, a desktop computer, a tablet, a device that connects to another peripheral device like a television or a desktop computer, etc.). In an embodiment, the electronic device 710 and the docking station 720 each include a MMW transceiver, such as the MMW transceiver 100 described above. The MMW transceiver included in the electronic device 710 and the docking station 720 may include the features described herein. The electronic device 710 and the docking station 720 can communicate via wireless data transmissions using the MMW transceiver. For example, the electronic device 710 can transmit data (e.g., RAW image files, video files, control signals, etc.) to the docking station 720 using the MMW transceiver. Likewise, the docking station 720 can transmit data (e.g., RAW image files, video files, control signals, etc.) to the electronic device 710 using the MMW transceiver.

In some embodiments, the MMW transceiver is internal to the electronic device 710 and/or the docking station 720. For example, the MMW transceiver could be included with other radios (e.g., GSM, CDMA, Bluetooth, etc.) in the electronic device 710 or docking station 720. In other embodiments, not shown, the MMW transceiver can be connected to the electronic device 710 and/or the docking station 720 via an external connection. For example, the MMW transceiver could be included in a device that connects to the electronic device 710 and/or the docking station 720 via a wired connection (e.g., via USB, Ethernet, IEEE 1394, etc.). Data can then be routed between the electronic device 710 or the docking station 720 and the MMW transceiver via the wired connection.

### Terminology

Although certain types of circuit components are shown and described herein, equivalent or similar circuit components may be used in their place in other embodiments. For instance, example field effect transistors (FETs) shown may be replaced with bipolar junction transistors (BJTs) in some embodiments. Further, NMOS FETs may be replaced with PMOS FETs and vice versa, or NPN BJTs may be replaced with PNP BJTs, and vice versa. Further, many types of FETs can be used interchangeably in the embodiments described herein with slight or no design differences, some examples of which include a CNFET, a DEPFET, a DNAFET, a FREDFET, a HEMT, an IGBT, an ISFET, a JFET, a MESFET, a MOSFET, a MODFET, a NOMFET, an OFET, and the like. Other circuit components shown, including passive components, may likewise be replaced with other electrical equivalents or similar circuits. Furthermore, the values of passive circuit elements, voltages, currents, and power (among other circuit parameters) may be chosen to satisfy any design criterion relevant to the electronic device in which the circuits are implemented.

Although the inventions disclosed herein have been described in the context of certain embodiments and examples, it should be understood that the inventions disclosed herein extend beyond the specifically disclosed embodiments to other alternative embodiments and/or uses of the inventions and certain modifications and equivalents thereof. Further, the disclosure herein of any particular feature, aspect, method, property, characteristic, quality, attribute, element, or the like in connection with an embodiment may be used in all other embodiments set forth herein. Thus, it is intended that the scope of the inventions disclosed herein should not be limited by the particular disclosed embodiments described above. As will be recognized, certain embodiments of the inventions described herein can be embodied within a form that does not provide all of the features and benefits set forth herein, as some features can be used or practiced separately from others.

Many other variations than those described herein will be apparent from this disclosure. For example, depending on the embodiment, certain acts, events, or functions of any of the methods described herein can be performed in a different sequence, can be added, merged, or left out altogether (e.g., not all described acts or events are necessary for the practice of the methods).

Conditional language used herein, such as, among others, “can,” “might,” “may,” “e.g.,” “for example,” “for instance,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list. Further, the term “each,” as used herein, in addition to having its ordinary meaning, can mean any subset of a set of elements to which the term “each” is applied.

While the above detailed description has shown, described, and pointed out novel features as applied to various embodiments, it will be understood that various omissions, substitutions, and changes in the form and details of the devices or algorithms illustrated can be made without departing from the spirit of the disclosure. As will be recognized, certain embodiments of the inventions described herein can be embodied within a form that does not provide all of the features and benefits set forth herein, as some features can be used or practiced separately from others.

What is claimed is:

1. A capacitor integrated circuit, comprising:
a top metal layer configured to store energy received from a transmission signal, the top metal layer comprising a first comb structure and a second comb structure, wherein the first comb structure is interleaved with the second comb structure to form a capacitor;
a bottom metal layer positioned underneath the top metal layer, the bottom metal layer configured to provide a path to ground; and
an intermediate metal layer positioned over the bottom metal layer and underneath at least a portion of the top metal layer, the intermediate metal layer configured to provide a signal path for a supply voltage.

2. The interdigitated capacitor of claim 1, further comprising a decoupling capacitor positioned between the intermediate metal layer and the bottom metal layer.

3. The interdigitated capacitor of claim 2, wherein the decoupling capacitor is positioned outside a location in which the top metal layer and the intermediate metal layer overlap.

4. The interdigitated capacitor of claim 2, wherein the decoupling capacitor is configured to provide a ground signal return path for the transmission signal.

5. The interdigitated capacitor of claim 1, wherein the supply voltage is received by the intermediate metal layer from a second intermediate metal layer of another circuit element.

6. The interdigitated capacitor of claim 1, further comprising a set of vias that couple the top metal layer with the intermediate metal layer.

7. A signal route layout, comprising:
a top metal layer configured to provide a path to ground;
a bottom metal layer positioned below the top metal layer, the bottom metal layer configured to provide a path to ground;
a first set of via sidewalls configured to couple a left side of the top metal layer to a left side of the bottom metal layer;
a second set of via sidewalls configured to couple a right side of the top metal layer to a right side of the bottom metal layer; and
an intermediate metal layer positioned between the top metal layer and the bottom metal layer and between the first set of via sidewalls and the second set of via sidewalls, the intermediate metal layer configured to provide a path for a transmission signal.

8. The signal route layout of claim 7, further comprising:
a silicon substrate; and
substrate contacts configured to couple the bottom metal layer to the silicon substrate.

9. The signal route layout of claim 8, wherein a noise level of the transmission signal is reduced from a first level to a second level when the substrate contacts couple the bottom metal layer to the silicon substrate.

10. The signal route layout of claim 8, wherein the substrate contacts are further configured to couple the top metal layer to the silicon substrate.

11. The signal route layout of claim 7, wherein the bottom metal layer comprises a hollow portion.

12. The signal route layout of claim 11, wherein the hollow portion is configured to filter a harmonic frequency from the transmission signal.

13. A signal route layout, comprising:
a top metal layer configured to provide a path for a transmission signal;
a bottom metal layer configured to provide a path for a non-transmission signal; and
an intermediate metal layer positioned between the top metal layer and the bottom metal layer, the intermediate metal layer configured to provide a path to ground.

14. The signal route layout of claim 13, wherein the bottom metal layer is positioned below the top metal layer.

15. The signal route layout of claim 13, wherein the bottom metal layer is positioned above the top metal layer.

16. The signal route layout of claim 13, wherein the non-transmission signal comprises a supply voltage signal.

17. The signal route layout of claim 13, wherein the non-transmission signal comprises a control signal.

18. The signal route layout of claim 13, wherein the top metal layer, the bottom metal layer, and the intermediate metal layer are sized to match foundry design rules.

19. A wireless data transceiver, comprising:
a wireless receiver;
a wireless transmitter; and
an interdigitated capacitor comprising:
a top metal layer configured to store energy received from a transmission signal, the top metal layer comprising a first comb structure and a second comb structure, wherein the first comb structure is interleaved with the second comb structure;
a bottom metal layer positioned underneath the top metal layer, the bottom metal layer configured to provide a path to ground; and
an intermediate metal layer positioned over the bottom metal layer and underneath at least a portion of the top metal layer, the intermediate metal layer configured to provide a signal path for a supply voltage.

20. The wireless data transceiver of claim 19, further comprising a decoupling capacitor positioned between the intermediate metal layer and the bottom metal layer.

21. The wireless data transceiver of claim 20, wherein the decoupling capacitor is positioned outside a location in which the top metal layer and the intermediate metal layer overlap.

22. The wireless data transceiver of claim 20, wherein the decoupling capacitor is configured to provide a ground signal return path for the transmission signal.

23. The wireless data transceiver of claim 19, wherein the supply voltage is received by the intermediate metal layer from a second intermediate metal layer of another circuit element.

24. The wireless data transceiver of claim 19, wherein the interdigitated capacitor further comprises a via sidewall that couples the top metal layer with the intermediate metal layer.

25. The wireless data transceiver of claim 19, further comprising a frequency mixer.

26. The wireless data transceiver of claim 19, further comprising a modem.

27. The wireless data transceiver of claim 19, further comprising a digital enhancement and control unit.

28. The wireless data transceiver of claim 19, wherein the wireless data transceiver consumes less than 250 mW of power when transmitting or receiving data.
